(19) United States
(12) Patent Application Publication
(10) Pub. No.: US 2024/0222130 A1
(43) Pub. Date: Jul. 4, 2024

(54) ENABLING COPPER RECESS FLATTENING THROUGH BLOCKED COPPER ETCHING PROCESSES

(71) Applicant: Intel Corporation, Santa Clara, CA (US)

(72) Inventors: Shaojiang CHEN, Chandler, AZ (US); Jeremy D. ECTON, Gilbert, AZ (US); Oladeji FADAYOMI, Maricopa, AZ (US); Hsin-Wei WANG, Chandler, AZ (US); Changhua LIU, Chandler, AZ (US); Bin MU, Tempe, AZ (US); Hongxia FENG, Chandler, AZ (US); Brandon C. MARIN, Gilbert, AZ (US); Srinivas V. PIETAMBARAM, Chandler, AZ (US)

(21) Appl. No.: 18/091,026

(22) Filed: Dec. 29, 2022

(51) Int. Cl. H01L 21/306; H01L 21/321; H01L 21/48; H01L 21/768

(52) U.S. Cl. CPC H01L 21/30604; H01L 21/3212; H01L 21/486; H01L 21/7688; H01L 21/76898; H01L 21/268

(57) ABSTRACT

Embodiments disclosed herein include electronic packages and methods of forming electronic packages. In an embodiment, an electronic package comprises a core, where the core comprises glass. In an embodiment, a through glass via (TGV) is provided through a thickness of the core. In an embodiment, the TGV comprises a top surface that is non-planar and includes a symmetric ridge on the non-planar top surface.

### TECHNICAL FIELD

Embodiments of the present disclosure relate to electronic packages, and more particularly to package architectures that include a glass core with through glass vias that include a flattened copper surface above the through glass vias.

### BACKGROUND

Glass core package architectures are one architecture that may be used to realize next-generation packaging solutions. Despite the advantages of glass cores, which include allowing for finer via pitch sizes, lower signal losses, lower total thickness variation, etc., plating copper on high aspect ratio through glass vias (TGVs) poses a problem of the undesirable overburden copper with recess features above the TGV regions. Avoiding such a problem during TGV plating has been a long-standing challenge. Current approaches to avoid recess transfer into TGVs include using chemical mechanical planarization (CMP) processes to flatten the copper surface. However, CMP has not been demonstrated as being a viable solution for high volume manufacturing due to its high cost and potential risks, such as glass panel breakage. Moreover, copper bulk etching has been used to remove bulk copper prior to the CMP flattening process. However, due to its isotropic etching nature, usage of this process alone transfers the copper recess into the TGVs, which poses a high risk on the downstream vias and metal-layer structures. This ultimately results in reliability issues.

### BRIEF DESCRIPTION OF THE DRAWINGS

FIG. 1 is a cross-sectional illustration of a portion of a through glass via (TGV) that includes a recess, in accordance with an embodiment.

FIG. 2 is a cross-sectional illustration of a portion of a TGV that includes a ridge on the top surface that is symmetric about a centerline of the TGV, in accordance with an embodiment.

FIGS. 3A-3F are cross-sectional illustrations depicting a process for forming a TGV with a top surface that is substantially flat with the inclusion of a ridge, in accordance with an embodiment.

FIG. 4A is a cross-sectional illustration of a portion of a TGV that includes a dished top surface, in accordance with an embodiment.

FIG. 4B is a cross-sectional illustration of a portion of a TGV that includes a dished top surface with a symmetric ridge, in accordance with an embodiment.

FIGS. 5A-5F are cross-sectional illustrations depicting a process for forming a TGV with a top surface that is substantially flat with a fluorination process, in accordance with an embodiment.

FIGS. 6A-6E are cross-sectional illustrations depicting a process for forming a TGV with a top surface that is substantially flat with a symmetric ridge structure, in accordance with an embodiment.

FIG. 7 is a cross-sectional illustration of a computing system that includes a glass core with TGVs that include a symmetric ridge on the top and bottom surfaces, in accordance with an embodiment.

FIG. 8 is a schematic of a computing device built in accordance with an embodiment.

### EMBODIMENTS OF THE PRESENT DISCLOSURE

Described herein are package architectures that include a glass core with through glass vias that include a flattened copper surface above the through glass vias, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

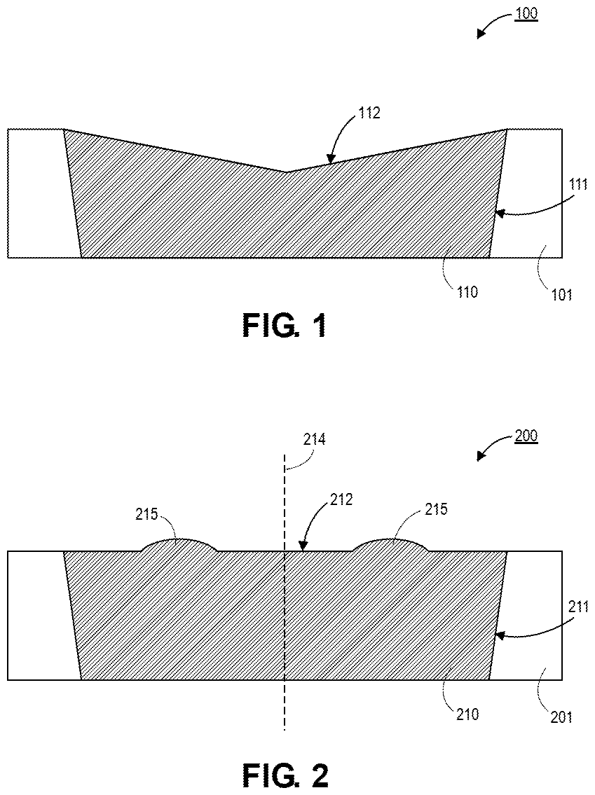

As noted above, glass core architectures are currently limited in the formation of through glass vias (TGVs). Particularly, the TGVs formed with current processes include overburden copper with a recess. Etching back the overburden results in the recess being transferred into the TGV. An example of such a structure 100 is shown in FIG. 1. As shown, a TGV 110 is provided in a core 101, such as a glass core 101. The TGV 110 may have sidewalls 111 that are tapered or otherwise sloped. Though, substantially vertical sidewalls 111 may also be present in some implementations. As shown, a top surface 112 of the TGV may include a recess that extends below a top surface of the core 101. The recess may have a maximum depth that is approximately 15 μm or greater in some implementations. The recess may be a substantially triangular shaped in some architectures. The presence of such a recess may result in reliability issues for downstream metal-layer and via structures.

In order to prevent the transfer of such recesses into TGVs, chemical mechanical planarization (CMP) processes may be used to flatten the recess above TGVs. However, CMP processes are expensive, and can potentially lead to cracking or other damage to the core 101. As such, CMP processes do not provide a pathway to high volume manufacturing solutions.

According, embodiments, disclosed herein include a modified copper bulk etching process that enables the flattening of copper recess above the TGVs. The proposed etching process is expected to enable anisotropic copper etching by blocking the recess regions. The recess regions may be blocked with various material systems. In one embodiment, a dry film resist (DFR) is deposited over the core and patterned to remain over the recess. In another embodiment, a sacrificial material, such as polyvinyl alcohol (PVOH) or poly(methyl methacrylate) (PMMA) can be provided on the recess. In yet another embodiment, a localized fluorination treatment over the recess can be used to block certain regions above the TGV (namely, the recess region).

Referring now to FIG. 2, a cross-sectional illustration of a portion of an electronic package 200 is shown, in accordance with an embodiment. In an embodiment, the electronic package 200 may comprise a core 201. The core 201 may be a glass core 201. For example, the core 201 may comprise a borosilicate glass, a fused silica glass, or the like. The core 201 may have a thickness that is between approximately 50 μm and approximately 1,000 μm. As used herein, “approximately” may refer to a range of values within ten percent of the stated value. For example, approximately 1,000 μm may refer to a range between 900 μm and 1,100 μm.

The core 201 may be formed from a glass formulation that is compatible with laser assisted patterning processes. In an embodiment, laser assisted patterning processes may include a laser exposure of the core 201. The laser exposure results in exposed regions undergoing phase and/or microstructure changes that render the exposed region more susceptible to an etching chemistry (e.g., a wet etching chemistry). The laser assisted patterning process may result in the formation of an opening into which the TGV 210 is deposited. Due to the laser assisted patterning process, the TGV 210 may have sidewalls 211 that are tapered or sloped. In the illustrated embodiment, only a top portion of the TGV 210 is shown for simplicity. It is to be appreciated that a bottom portion may be substantially similar to the top portion. Additionally, the TGV 210 may have an hourglass shaped cross-section, as will be described in greater detail below.

In an embodiment, the top surface 212 of the TGV 210 may be substantially flat. As used herein, substantially flat may refer to a surface that has maximum feature standoffs that are less than approximately 20 μm. In some embodiments, the feature standoffs may be approximately 10 μm or less, or approximately 5 μm or less.

In some embodiments, the etching processes described herein result in the formation of a ridge 215. In the cross-sectional illustration, the ridge 215 is shown as a pair of structures that extend up from the top surface 212 of the TGV 210. However, it is to be appreciated that the ridges 215 shown in FIG. 2 may be connected to each other out of the plane of FIG. 2 to form a ring shaped ridge 215 or the like. In an embodiment, the ridge 215 may be substantially symmetric about a centerline 214 of the TGV 210. That is, the ridge 215 on the left may have a shape that is substantially mirrored by a shape of the ridge 215 on the right. In some embodiments, the left ridge 215 may be substantially the same distance from the centerline 214 as the right ridge 215. Though, in some embodiments, the ridge 215 may be offset from the centerline 214 as a result of patterning misalignments or the like.

In an embodiment, the ridge 215 may have a standoff height that is less than approximately 20 μm, less than approximately 10 μm, or less than approximately 5 μm. The ridge 215 may be the residual feature that persists into the final structure after the etching processes disclosed herein. That is, the etching processes disclosed herein may not provide a perfectly flat surface on the top surface 212 of the TGV 210. Though, it is to be appreciated that the smaller features (e.g., ridge 215) are more compatible with subsequent patterning and deposition processes, and reduces the risk of reliability issues in the structure.

In the illustrated embodiment, the ridges 215 are shown as being substantially symmetric about their centerline. That is, an inner surface of the ridge 215 may be substantially similar to an outer surface of the ridge 215. Though, embodiments are not limited to such configurations. For example, the inner surface of the ridge 215 may have a different profile than an outer surface of the ridge 215, as will be described in greater detail below.

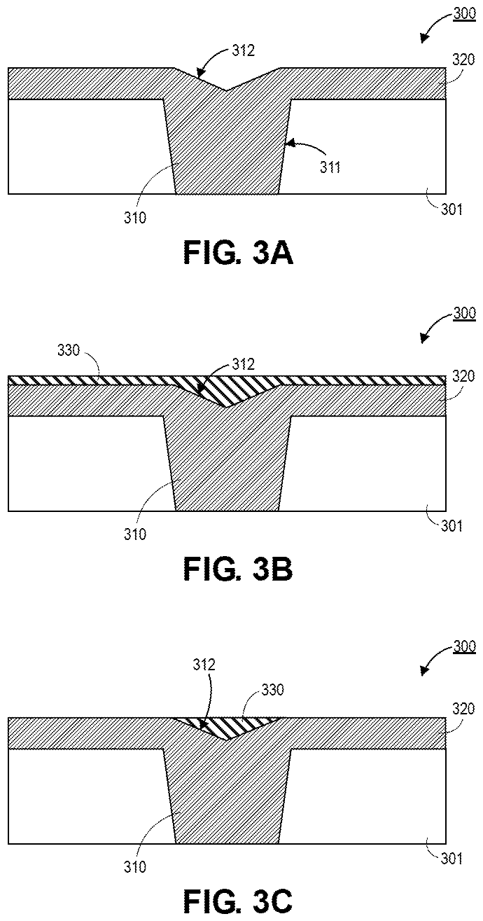

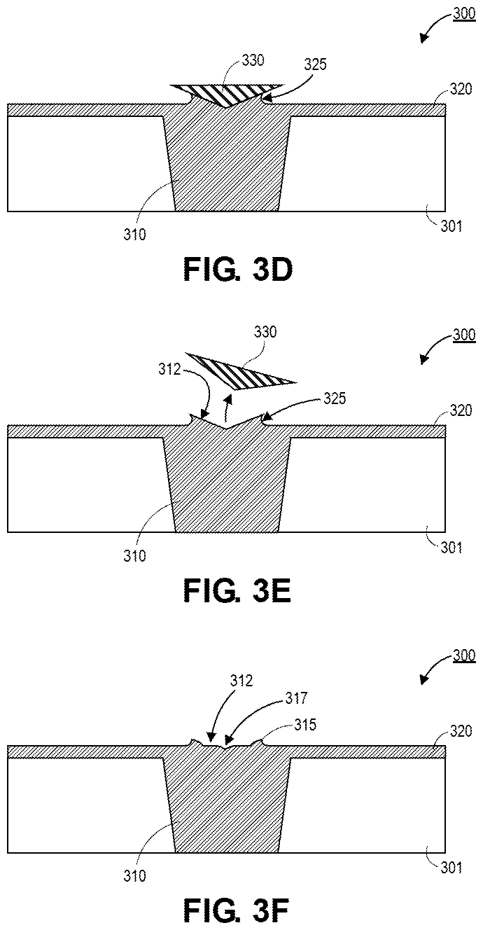

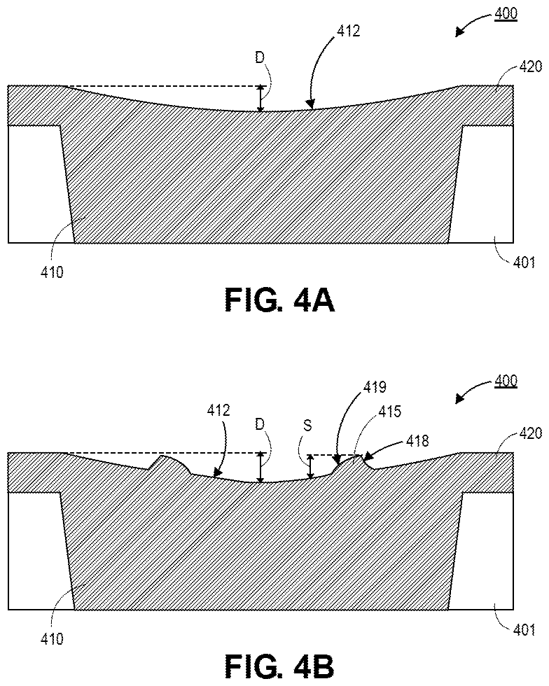

Referring now to FIGS. 3A-3F, a series of cross-sectional illustrations depicting a process for minimizing the presence of a recess in the top surface 312 of a TGV 310 is shown, in accordance with an embodiment. In an embodiment, a sacrificial layer is provided in the recess. The sacrificial layer may be a material that blocks the etching of the underlying TGV 310. The sacrificial layer may then be removed after the profile of the recess is minimized. The resulting structure may include a ridge 315 over the top surface of the TGV 310.

Referring now to FIG. 3A, a cross-sectional illustration of a portion of an electronic package 300 is shown, in accordance with an embodiment. In an embodiment, the electronic package 300 comprises a core 301. The core 301 may include a glass core 301. The glass core 301 may be similar to the glass core 201 described in greater detail above.

In an embodiment, a TGV 310 is provided in the core 301. The TGV 310 may have sidewalls 311 that are tapered. The sidewalls 311 may be tapered in order to provide an hourglass shaped cross-section for the TGV 310. Though, in FIG. 3A only the top portion of the TGV 310 is shown for simplicity. It is to be appreciated that substantially similar processes and structures may be formed on the bottom side of the TGV 310. The TGV 310 may comprise any suitable electrically conductive feature, such as copper or the like. While shown as a single monolithic structure, it is to be appreciated that the TGV 310 may also comprise seed layers or the like.

In an embodiment, an overburden layer 320 may be provided over the top surface of the core 301. The overburden layer 320 may also comprise copper or the like. In an embodiment, a recess is provided in a top surface 312 of the TGV 310. The recess may be the result of deposition processes used to form high aspect ratio features of the TGV 310. Without further processing, such as what will be described herein, the recess will transfer into the TGV 310 below the top surface of the core 301 when the overburden layer 320 is removed.

Referring now to FIG. 3B, a cross-sectional illustration of the electronic package 300 after a sacrificial layer 330 is provided over the TGV 310 and the overburden layer 320 is shown, in accordance with an embodiment. The sacrificial layer 330 may be any number of suitable materials. Suitable materials may include materials that have an etch selectivity to copper or other metal used for the overburden layer 320 and the TGV 310. In one instance, the sacrificial layer 330 may be a dry film resist (DFR). In other embodiments, the sacrificial layer 330 may be a polyvinyl alcohol (PVOH) or a poly (methyl methacrylate) (PMMA). The sacrificial layer 330 may be deposited with a lamination process, a slit coating process, a spin coating process, a deposition process, or the like. In some embodiments, the sacrificial layer 330 may be cured after deposition.

The sacrificial layer 330 may completely fill the recess over the top surface 312 of the TGV 310. The sacrificial layer 330 may also be disposed over the top surface of the overburden layer 320. In some instances, the top surface of the sacrificial layer 330 may be substantially flat. This results in a portion of the sacrificial layer 330 that is above the TGV 310 being thicker than a portion of the sacrificial layer 330 that is above the overburden layer 320.

Referring now to FIG. 3C, a cross-sectional illustration of the electronic package 300 after the sacrificial layer 330 is recessed is shown, in accordance with an embodiment. In an embodiment, the sacrificial layer 330 may be recessed using any suitable patterning process. In one embodiment, a timed etching process is used to expose the overburden layer 320 while leaving a portion in the copper recess. In other embodiments, an etching process that uses endpoint detection may be used in order to stop the etching process once the overburden layer 320 is exposed. In a particular embodiment, the residual sacrificial layer 330 may have a substantially triangular cross-section. Though, residual sacrificial layer 330 may have any cross-section shape, depending on the shape of the copper recess.

As shown, the residual sacrificial layer 330 remains substantially over the TGV 310, and the remaining portion of the overburden layer 320 is exposed. As such, an isotropic etching process can be used to reduce the thickness of the overburden layer 320 without etching the bottom of the recess. This allows for the thicker overburden layer 320 to be removed without transferring the recess into the TGV 310 below a top surface of the core 301.

Referring now to FIG. 3D, a cross-sectional illustration of the electronic package 300 during an etching process is shown, in accordance with an embodiment. In an embodiment, the etching process is an isotropic etching process, such as a wet etching process. The etching process results in the thickness of the overburden layer 320 being reduced. The sacrificial layer 330 protects the top surface of the recess. Further, due to the isotropic nature of the etching process, the copper at the edge below the sacrificial layer 330 can be consumed. As shown, an undercut surface 325 is provided below the sacrificial layer 330. This undercutting action allows for portions of the recess structure to be removed laterally instead of being transferred down into the underlying TGV 310.

Referring now to FIG. 3E, a cross-sectional illustration of the electronic package 300 after the sacrificial layer 330 is removed is shown, in accordance with an embodiment. The sacrificial layer 330 may be mechanically removed from the surface 312 as a result of the undercutting 325. In other embodiments, an etching process, a delamination process, a dissolving process, or any other suitable process may be used to remove the sacrificial layer 330, as indicated by the arrow. Removal of the sacrificial layer 330 results in the re-exposure of the top surface 312. However, due to the undercutting, the depth of the recess has been significantly reduced.

Referring now to FIG. 3F, a cross-sectional illustration of the electronic package 300 after further etching is shown, in accordance with an embodiment. As shown, the additional isotropic etching results in the formation of ridges 315 that extend out from the top surface 312 of the TGV 310. A small recess 317 may also be present in some embodiments. At this point, the profile of the top surface 312 may be fully transferred into the TGV 310 through etching the remainder of the overburden layer 320. However, instead of a structure with a recess that is approximately 20 μm or greater, the top surface 312 is smoothed and may have features (e.g., recess 317 or ridges 315) that have standoffs up to approximately 10 μm, or up to approximately 5 μm.

Referring now to FIG. 4A, a cross-sectional illustration of a portion of an electronic package 400 is shown, in accordance with an embodiment. The electronic package 400 may comprise a core 401, such as a glass core 401. A TGV 410 may be provided in the core 401. Overburden 420 may be provided over a top surface of the core 401 in some embodiments. As shown, a top surface 412 of the TGV 410 may be dished. That is, the top surface 412 may curve down to a maximum depth at an approximate center of the TGV 410. However, instead of having a significant recess (e.g., approximately 15 μm or greater), the top surface may have a maximum depth D that is up to approximately 10 μm, or up to approximately 5 μm. The dished shape may be the result of processing such as the processing disclosed in greater detail above with respect to FIGS. 3A-3F. In the illustrated embodiment, the surface 412 is smoothly curved. Such an embodiment may be the ideal surface 412 profile provided by the etching process. With further isotropic etching, the smooth dish profile may be transferred into the TGV 410. That is, the top surface 412 may be provided below the top surface of the core 401 in some embodiments.

However, it is to be appreciated that an ideal surface 412 profile may not be obtained in all instances of the etching process described in greater detail above. Accordingly, FIG. 4B is provided in order to more clearly demonstrate a profile that includes a ridge 415 that may be a residual indication that such an etching process was used. As shown in FIG. 4B, the top surface 412 is dished with a maximum depth D. The depth D may be up to approximately 10 μm, or up to approximately 5 μm. Instead of being a smooth curved surface, the top surface 412 may include a ridge 415. In the cross-sectional illustration of FIG. 4B, a left ridge 415 and a right ridge 415 is shown. However, it is to be appreciated that the left ridge 415 and the right ridge 415 may be connected to each other out of the plane of FIG. 4B. For example, the ridge 415 may be a ring with an outer surface and an inner surface.

In an embodiment, the ridge 415 may be substantially symmetric about a centerline of the TGV 410. That is, the left ridge 415 may be equidistant to the centerline of the TGV 410 with the right ridge 415. Though, offsets inherent in the patterning of the sacrificial layer may result in the ridge 415 being offset from the centerline of the TGV 410 in some embodiments. Regardless of the positioning with respect to the centerline of the TGV 410, the left ridge 415 may be substantially a mirror image of the right ridge 415. That is, outer surfaces 418 may have substantially similar (though mirrored) profiles, and inner surfaces 419 may have substantially similar (though mirrored) profiles. In a particular embodiment, the outer surfaces 418 are concave and the inner surfaces 419 are convex. Though, depending on the etching process, the inner surfaces 419 and the outer surfaces 418 may have either concave or convex surfaces.

In an embodiment, a standoff height S of the ridge 415 may be less than approximately 20 μm. In a particular embodiment, the standoff height S of the ridge 415 may be approximately 10 μm or less, or approximately 5 μm or less. The smaller standoff height S (compared to an untreated recess depth of 20 μm or greater) allows for improved reliability in subsequent processing operations. Further while a globally dished profile with ridges 415 is shown, it is to be appreciated that the ridges 415 may rise up from a substantially flat surface in some embodiments. That is, the surface 412 may not be dished in some embodiments.

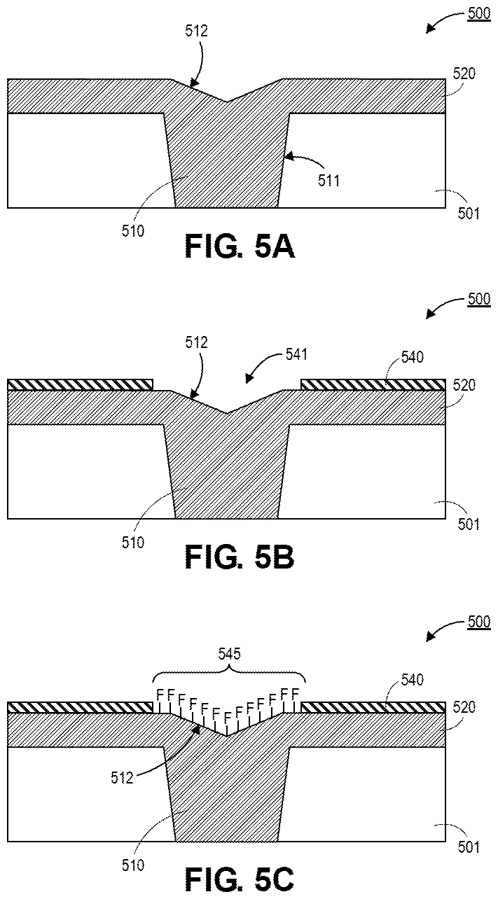

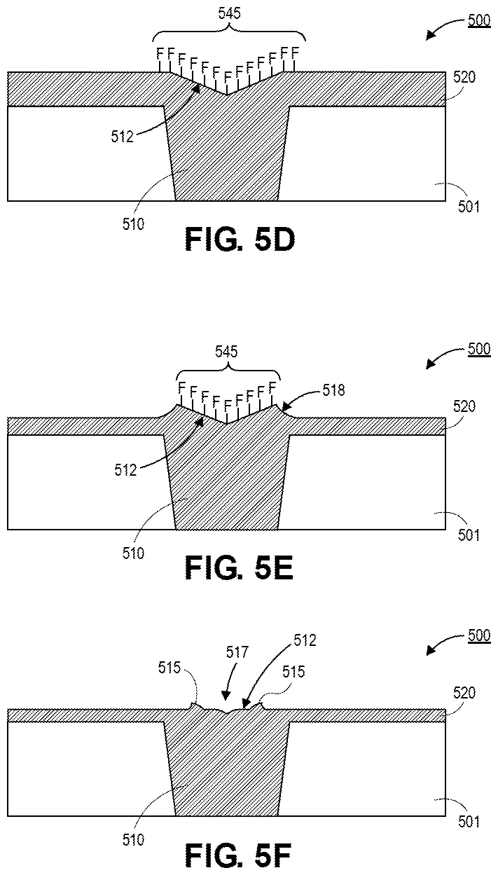

Referring now to FIGS. 5A-5F, a series of cross-sectional illustrations of a process for minimizing or eliminating a recess in the copper above a TGV 510 is shown, in accordance with an embodiment. Particularly, the embodiment shown in FIGS. 5A-5F includes a fluorination process that results in a surface-hydrophobization that repels the etching chemistry. The overburden can then be reduced and the recess is undercut in order to minimize the recess without transferring the recess into the TGV 510.

Referring now to FIG. 5A, a cross-sectional illustration of a portion of an electronic package 500 is shown, in accordance with an embodiment. In an embodiment, the electronic package 500 comprises a core 501. The core 501 may include a glass core 501. The glass core 501 may be similar to the glass core 201 described in greater detail above.

In an embodiment, a TGV 510 is provided in the core 501. The TGV 510 may have sidewalls 511 that are tapered. The sidewalls 511 may be tapered in order to provide an hourglass shaped cross-section for the TGV 510. Though, in FIG. 5A only the top portion of the TGV 510 is shown for simplicity. It is to be appreciated that substantially similar processes and structures may be formed on the bottom side of the TGV 510. The TGV 510 may comprise any suitable electrically conductive feature, such as copper or the like. While shown as a single monolithic structure, it is to be appreciated that the TGV 510 may also comprise seed layers or the like.

In an embodiment, an overburden layer 520 may be provided over the top surface of the core 501. The overburden layer 520 may also comprise copper or the like. In an embodiment, a recess is provided in a top surface 512 of the TGV 510. The recess may be the result of deposition processes used to form high aspect ratio features of the TGV 510. Without further processing, such as what will be described herein, the recess will transfer into the TGV 510 below the top surface of the core 501 when the overburden layer 520 is removed.

Referring now to FIG. 5B, a cross-sectional illustration of the electronic package 500 after a resist layer 540 is deposited and patterned is shown, in accordance with an embodiment. In an embodiment, the resist layer 540 may be a DFR or the like. The resist layer 540 may be deposited with a lamination process or the like. After the resist layer 540 is provided over the core 501, the resist layer 540 is exposed to electromagnetic radiation and developed. The developing process may result in the formation of an opening 541 through the resist layer 540. The opening 541 may be substantially centered over the recess in the top surface 512. The opening 541 may be wider than the recess in some embodiments. Though, in other embodiments, the opening 541 may be substantially the same width as the recess or even narrower than the width of the recess.

Referring now to FIG. 5C, a cross-sectional illustration of the electronic package 500 after a surface-hydrophobization process is shown, in accordance with an embodiment. The surface-hydrophobization process may result in the formation of a hydrophobic surface 545 over the surface 512. The hydrophobic surface 545 may comprise a layer with fluorine (F) terminations or any other hydrophobic chemical structure. In a particular embodiment, the surface-hydrophobization process is a fluorination treatment. For example, a fluorine containing solution may be dispensed over the surface 512. The resist layer 540 prevents the hydrophobization of the portions of the overburden layer 520 outside of the opening 541. As such, a hydrophilic region (under the resist layer 540) and a hydrophobic surface 545 are provided. The wet etching chemistry will be repelled by the hydrophobic surface 545 and preferentially etch outside of the recess above the TGV 510.

Referring now to FIG. 5D, a cross-sectional illustration of the electronic package 500 after the resist layer 540 is removed is shown, in accordance with an embodiment. In an embodiment, the resist layer 540 may be removed with a process that does not substantially interfere with the hydrophobic surface 545. For example, a resist stripping process or the like may be used to remove the resist layer 540. After removal of the resist layer 540 portions of the overburden layer 520 are exposed.

Referring now to FIG. 5E, a cross-sectional illustration of the electronic package 500 during an etching process is shown, in accordance with an embodiment. In an embodiment, the etching process may be an isotropic etching process, such as a wet etching process. The overburden layer 520 may be reduced in thickness by the etching process. In an embodiment, the etching process may also include material removal from below the hydrophobic surface 545. Particularly, a lateral etching direction may occur. That is, the top surface 512 is protected by the hydrophobic surface 545, but an undercutting process occurs, as indicated by the etching surface 518. The undercut may not be clearly illustrated in FIG. 5E, because portions of the hydrophobic surface 545 (e.g., at the ends of the hydrophobic surface 545) are released as the undercutting etch continues on to the center of the TGV 510.

Referring now to FIG. 5F, a cross-sectional illustration of the electronic package 500 after the surface 512 is flattened is shown, in accordance with an embodiment. In an embodiment, the flattened surface 512 may be the result of the lateral undercutting below the hydrophobic surface 545. Consumption of copper in the undercut may release the hydrophobic surface 545, so that it is substantially removed at the end of the etching process. In an embodiment, the flat surface 512 may include a ridge 515 and/or a small recess 517.

In an embodiment, the flat surface 512 may be substantially similar to the surfaces 412 shown in FIG. 4A or 4B. That is, ridges 515 may be symmetric and be substantially mirror images of each other. In an embodiment, the ridges 515 may have a standoff height that is approximately 10 μm or less, or approximately 5 μm or less. In an embodiment, the outer surfaces of the ridges 515 may have a different profile than inner surfaces of the ridges 515. The small recess 517 may be a dished surface in some embodiments. For example, the top surface 512 may be globally dished with one or more ridges extending up from the dished top surface 512. The recess 517 may have a depth up to approximately 10 μm, or up to approximately 5 μm. As the top surface 512 is continued to be etched with an isotropic etching chemistry, the minimal topography of the ridges 515 and the recess 517 may be transferred into the TGV 510. The minimal topography of the surface 512 allows for high reliability of subsequent processing operations.

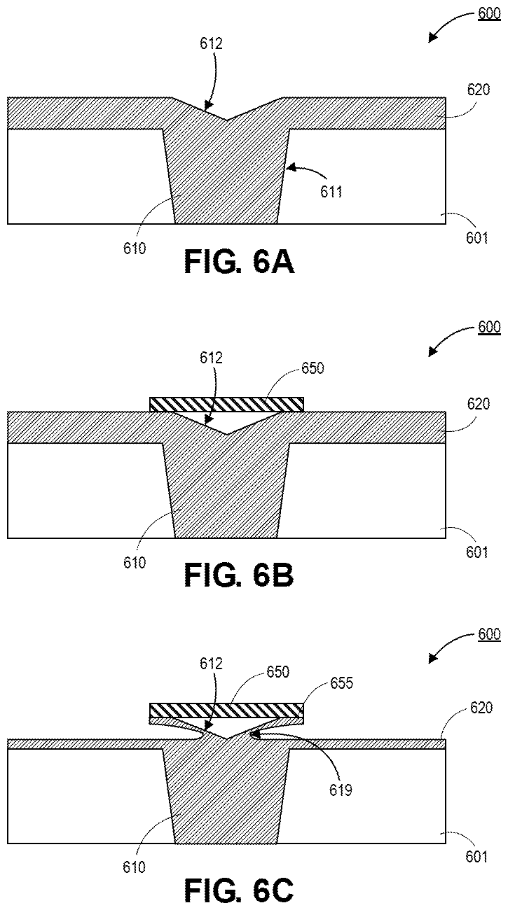

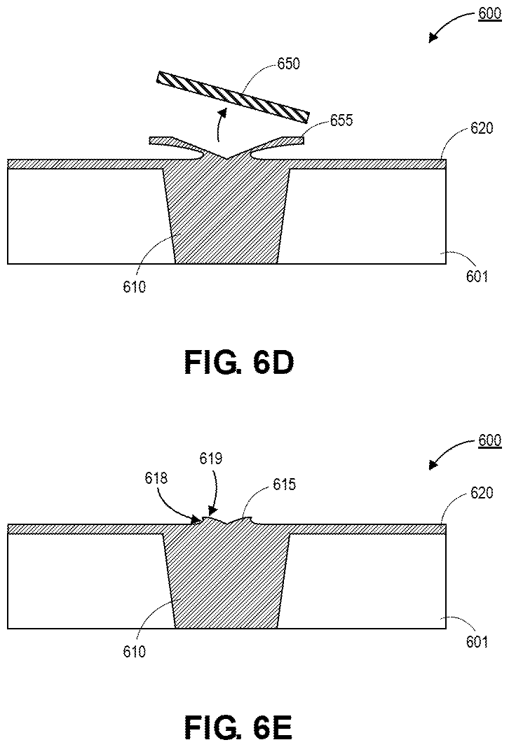

Referring now to FIGS. 6A-6E, a series of cross-sectional illustrations depicting a process for forming an electronic package 600 with a TGV 610 that previously had a recess in the top surface is shown, in accordance with an embodiment. An etching process is used in order to minimize any topography and reduce the depth of the recess or eliminate the recess completely. In some embodiments, the portion of the TGV 610 with the recess is masked and an etching process is used to etch around the recess. An undercut is provided below the recess to form wings. The wings are then etched back or mechanically detached to leave behind a ridge that has minimal topography.

Referring now to FIG. 6A, a cross-sectional illustration of a portion of an electronic package 600 is shown, in accordance with an embodiment. In an embodiment, the electronic package 600 comprises a core 601. The core 601 may include a glass core 601. The glass core 601 may be similar to the glass core 201 described in greater detail above.

In an embodiment, a TGV 610 is provided in the core 601. The TGV 610 may have sidewalls 611 that are tapered. The sidewalls 611 may be tapered in order to provide an hourglass shaped cross-section for the TGV 610. Though, in FIG. 6A only the top portion of the TGV 610 is shown for simplicity. It is to be appreciated that substantially similar processes and structures may be formed on the bottom side of the TGV 610. The TGV 610 may comprise any suitable electrically conductive feature, such as copper or the like. While shown as a single monolithic structure, it is to be appreciated that the TGV 610 may also comprise seed layers or the like.

In an embodiment, an overburden layer 620 may be provided over the top surface of the core 601. The overburden layer 620 may also comprise copper or the like. In an embodiment, a recess is provided in a top surface 612 of the TGV 610. The recess may be the result of deposition processes used to form high aspect ratio features of the TGV 610. Without further processing, such as what will be described herein, the recess will transfer into the TGV 610 below the top surface of the core 601 when the overburden layer 620 is removed.

Referring now to FIG. 6B, a cross-sectional illustration of the electronic package 600 after a resist layer 650 is disposed over the top surface 612 over the recess is shown, in accordance with an embodiment. In an embodiment, the resist layer 650 may be a DFR or the like. The resist layer 650 may be laminated over the top surface, exposed to electromagnetic radiation, and developed in order to provide the structure shown in FIG. 6B. As shown, the resist layer 650 entirely covers the top surface 612 of the recess. The resist layer 650 may also extend past edges of the recess in some embodiments. In the illustrated embodiment, the resist layer 650 spans across the recess. However, in other embodiments, the resist layer 650 may conform to the surface 612 and fill the recess. When filling the recess, the resist layer 650 may maintain a planar top surface.

Referring now to FIG. 6C, a cross-sectional illustration of the electronic package after an etching process is shown, in accordance with an embodiment. In an embodiment, the etching process may be a wet etching process. The etching process may generally be isotropic in nature. However, since the resist layer 650 blocks the top surface of the recess, an undercut 619 is formed below the surface 612. The undercutting process may result in the formation of wings 655 that extend up from the overburden layer 620 over the TGV 610.

Referring now to FIG. 6D, a cross-sectional illustration of the electronic package after the resist layer 650 is removed is shown, in accordance with an embodiment. As indicated by the arrow, the resist layer 650 may be mechanically removed from the wings 655. Though, in other embodiments a resist stripping or dissolving process may be used to remove the resist layer 650.

Referring now to FIG. 6E, a cross-sectional illustration of the electronic package after the wings 655 and the overburden layer 620 are further etched is shown, in accordance with an embodiment. Since the wings 655 have a relatively large surface area and can be etched from multiple directions, the wings 655 can be etched down to ridges 615 over the TGV 610. In an embodiment, the outer surfaces 618 of the ridges 615 may have a concave shape. A top surface 619 of the ridge 615 may be substantially flat and parallel to the top surface of the core 601. While a particular architecture for the ridge 615 is shown, it is to be appreciated that etching processes may result in ridge architectures that are substantially similar to any of the ridge structures described in greater detail herein. Generally, the ridge may be a symmetric structure that may be aligned about a centerline of the TGV 610. With additional isotropic etching, the flat surface 612 will be substantially transferred into the top surface of the TGV 610.

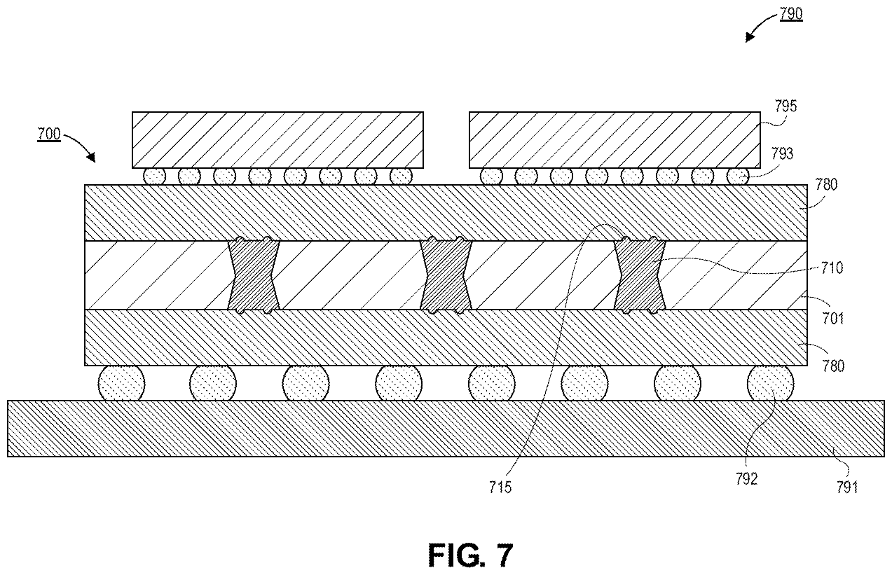

Referring now to FIG. 7, a cross-sectional illustration of a computing system 790 is shown, in accordance with an embodiment. In an embodiment, the computing system 790 comprises a board 791, such as a printed circuit board (PCB). The board 791 may be coupled to an electronic package 700 through interconnects 792, such as solder balls, sockets, or the like.

In an embodiment, the electronic package 700 comprises a package substrate with a core 701. In a particular embodiment, the core 701 is a glass core. The core 701 may comprise one or more TGVs 710. The TGVs 710 may have hourglass shaped cross-sections. In an embodiment, the top surface and the bottom surface of the TGVs 710 may be substantially flat with the exception of ridges 715. The ridges 715 may be residual structures that are remnants of an etching process used to reduce or eliminate the presence of recess in the TGVs 710. The ridges 715 may be symmetric about a centerline of the TGVs 710. In other embodiments, the ridges 715 may be similar to any of the ridge architectures described in greater detail herein.

In an embodiment, buildup layers 780 may be provided above and below the core 701. The buildup layers 780 may comprise conductive routing (e.g., pads, traces, vias, etc.) in order to provide electrical routing through the electronic package 700. For example, conductive routing may be coupled to the one or more dies 795 coupled to the package substrate. For example, first level interconnects (FLIs) 793 may couple the dies 795 to the buildup layers 780.

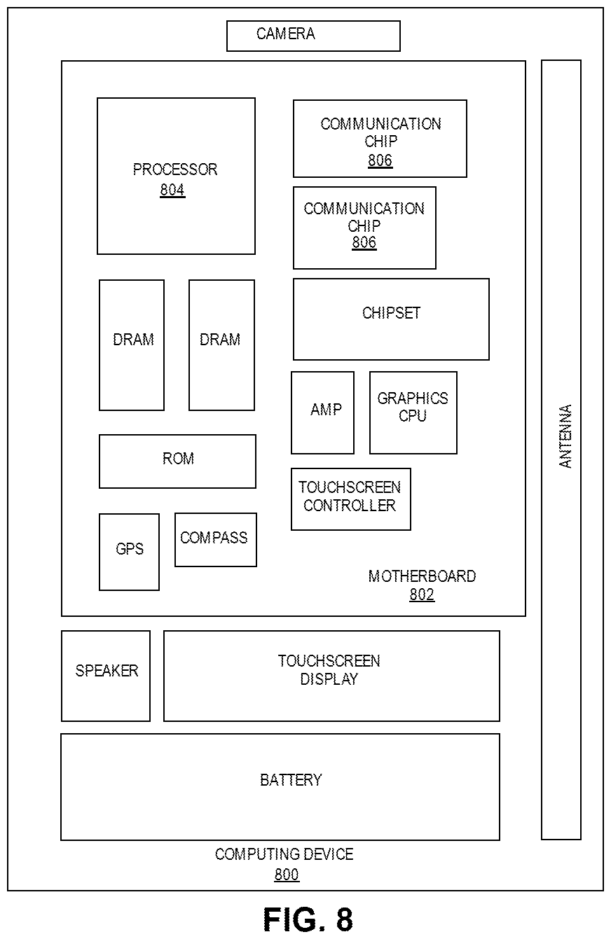

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a glass core with TGVs that include substantially flat top and bottom surfaces that may include ridges that have a standoff height that is less than approximately 10 μm, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a glass core with TGVs that include substantially flat top and bottom surfaces that may include ridges that have a standoff height that is less than approximately 10 μm, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.
Example 1: an electronic package, comprising: a core, wherein the core comprises glass; and a through glass via (TGV) through a thickness of the core, wherein the TGV comprises a top surface that is non-planar and includes a symmetric ridge on the non-planar top surface.
Example 2: the electronic package of Example 1, wherein the non-planar surface is a dished surface, and wherein the symmetric ridge extends up from the dished surface.
Example 3: the electronic package of Example 1 or Example 2, wherein the symmetric ridge is symmetric about a centerline of the TGV.
Example 4: the electronic package of Examples 1-3, wherein the symmetric ridge has a standoff height up to approximately 10 μm.
Example 5: the electronic package of Example 4, wherein the standoff height is up to approximately 5 μm.
Example 6: the electronic package of Examples 1-5, wherein the TGV comprises a bottom surface that is non-planar and includes a symmetric ridge on the non-planar bottom surface.
Example 7: the electronic package of Examples 1-6, wherein the TGV has
sloped sidewalls.
Example 8: the electronic package of Example 7, wherein the TGV has an hourglass shaped cross-section.
Example 9: the electronic package of Examples 1-8, wherein the electronic package is part of a computing system for a personal computer, a server, a mobile device, a tablet, or an automobile.
Example 10: a method of forming a through glass via (TGV), comprising: forming the TGV in a glass core, wherein the TGV has a recess on the top surface; filling the recess with a sacrificial layer; etching the TGV, wherein the sacrificial layer is undercut with the etching process; and removing the sacrificial layer.
Example 11: the method of Example 10, wherein the undercut forms a symmetric ridge structure above the TGV.
Example 12: the method of Example 11, wherein the ridge structure has a standoff height up to approximately 10 μm.
Example 13: the method of Examples 10-12, wherein the top surface of the TGV is dished.
Example 14: the method of Examples 10-13, wherein the sacrificial layer is a dry film resist.
Example 15: the method of Examples 10-13, wherein the sacrificial layer is a polyvinyl alcohol (PVOH) or a poly (methyl methacrylate) (PMMA).
Example 16: a method of forming a through glass via (TGV), comprising: forming the TGV in a glass core, wherein the TGV has a recess on the top surface; providing a resist layer over the top surface of the TGV; forming an opening over the recess; fluorinating the recess; removing the resist layer; etching the TGV, wherein the fluorinated recess is undercut with the etching process; and removing the fluorination layer.
Example 17: the method of Example 16, wherein the undercut forms a symmetric ridge structure above the TGV.
Example 18: the method of Example 17, wherein the ridge structure has a standoff height up to approximately 10 μm.
Example 19: the method of Example 17 or Example 18, wherein the ridge structure is symmetric about a centerline of the TGV.
Example 20: the method of Examples 16-19, wherein the resist layer is a dry film resist.

What is claimed is:

1. An electronic package, comprising:
a core, wherein the core comprises glass; and
a through glass via (TGV) through a thickness of the core, wherein the TGV comprises a top surface that is non-planar and includes a symmetric ridge on the non-planar top surface.

2. The electronic package of claim 1, wherein the non-planar surface is a dished surface, and wherein the symmetric ridge extends up from the dished surface.

3. The electronic package of claim 1, wherein the symmetric ridge is symmetric about a centerline of the TGV.

4. The electronic package of claim 1, wherein the symmetric ridge has a standoff height up to approximately 10 μm.

5. The electronic package of claim 4, wherein the standoff height is up to approximately 5 μm.

6. The electronic package of claim 1, wherein the TGV comprises a bottom surface that is non-planar and includes a symmetric ridge on the non-planar bottom surface.

7. The electronic package of claim 1, wherein the TGV has sloped sidewalls.

8. The electronic package of claim 7, wherein the TGV has an hourglass shaped cross-section.

9. The electronic package of claim 1, wherein the electronic package is part of a computing system for a personal computer, a server, a mobile device, a tablet, or an automobile.

10. A method of forming a through glass via (TGV), comprising:
forming the TGV in a glass core, wherein the TGV has a recess on the top surface;
filling the recess with a sacrificial layer;
etching the TGV, wherein the sacrificial layer is undercut with the etching process; and
removing the sacrificial layer.

11. The method of claim 10, wherein the undercut forms a symmetric ridge structure above the TGV.

12. The method of claim 11, wherein the ridge structure has a standoff height up to approximately 10 μm.

13. The method of claim 10, wherein the top surface of the TGV is dished.

14. The method of claim 10, wherein the sacrificial layer is a dry film resist.

15. The method of claim 10, wherein the sacrificial layer is a polyvinyl alcohol (PVOH) or a poly (methyl methacrylate) (PMMA).

16. A method of forming a through glass via (TGV), comprising:
forming the TGV in a glass core, wherein the TGV has a recess on the top surface;
providing a resist layer over the top surface of the TGV;
forming an opening over the recess;
fluorinating the recess;
removing the resist layer;
etching the TGV, wherein the fluorinated recess is undercut with the etching process; and
removing the fluorination layer.

17. The method of claim 16, wherein the undercut forms a symmetric ridge structure above the TGV.

18. The method of claim 17, wherein the ridge structure has a standoff height up to approximately 10 μm.

19. The method of claim 17, wherein the ridge structure is symmetric about a centerline of the TGV.

20. The method of claim 16, wherein the resist layer is a dry film resist.
